(19) United States
(12) Patent Application Publication
(10) Pub. No.: US 2026/0308050 A1
(43) Pub. Date: Oct. 8, 2026

(54) GLASS MICROSTRUCTURE, MICRO-MECHANICS, AND ASSOCIATED USE

(71) Applicant: LPKF Laser & Electronics SE, Garbsen (DE)

(72) Inventors: Roman Ostholt; Norbert AMBROSIUS, Garbsen (DE); Maik BERTKE, Hannover (DE); Svenja SCHUDAK, Hannover (DE); Michael LOOTZE, Garbsen (DE); Julia SZIEDAT, Bükeburg (DE)

(73) Assignee: LPKF Laser & Electronics SE, Garbsen (DE)

(21) Appl. No.: 18/880,433

(22) PCT Filed: Jul. 5, 2023
(86) PCT No.: PCT/EP2023/068495

§ 371 Date: Dec. 31, 2024

(30) Foreign Application Priority Data
Jul. 5, 2022 (DE) 102022116783.6

(51) Int. Cl. C03C 23/00; C03C 15/00

(52) U.S. Cl. CPC C03C 23/0025; C03C 15/00

(57) ABSTRACT

In order to expand the possible applications of the known LIDE (laser-induced deep etching) method, in the production of a micromechanical microstructure (1) by placing a multiplicity of laser pulses (4) on a glass substrate (3) with a subsequent wet-chemical etching step for exposing the microstructure (1), the position of the laser pulses (4) which define the outer contour (6) of the microstructure (1) is precisely controlled. In this way it becomes possible to control a spatial phase position φ of mutually opposite laser pulses or laser points (4), which are arranged on both sides of the microstructure (1), and form a respective laser pulse pair (18), but also an extent of what is known as sidewall scalloping. By controlling the phase position φ and/or the sidewall scalloping, it is possible to influence or set in a targeted manner the mechanical properties of the microstructure (1) favorably/in the desired form.

### CROSS-REFERENCE TO RELATED APPLICATIONS

This application is aa 371 National Phase of PCT/EP2023/068495, filed Jul. 5, 2023, which claims priority from German Patent Application No. 10 2022 116 783.6, filed Jul. 5, 2022, both of which are incorporated herein by reference as if fully set forth.

### TECHNICAL FIELD

The invention relates to a microstructure made of glass, which can be embodied in particular in the form of a micromechanical bending structure (which may form, for example, a micromechanical spring element) or for example in the form of movable fingers of a micromechanical comb structure or in the form of a cantilever. The microstructure is (completely/entirely) exposed by etching from a glass substrate using laser-induced deep etching (LIDE), that is to say using laser-induced depth etching, that is to say exposed by laser-induced modification of the glass substrate and subsequently anisotropic wet-chemical etching.

The invention further relates to a (movable) micromechanical system, which comprises (at least) a microstructure of this type, to a specific use of a micromechanical system of this type, which can likewise be produced using the LIDE method, and finally to an associated production method.

### BACKGROUND

The LIDE method is already known, for example from patent specification EP 2964417 B1. Until now, it has frequently been used to etch structures into glass substrates which form for example a housing of a sensor. The invention relates to the matter of how the applications of the LIDE method can be extended.

In the LIDE method, a material change (modification) is (optically) introduced into the glass body with the aid of a single laser pulse, typically over an entire thickness of a glass substrate, which change leads to the fact that in a subsequent wet-chemical etching step, the structure which has been thus optically pre-treated using the laser/exposed to the laser can be anisotropically etched in the glass substrate, even though the etching solution actually shows isotropic etching properties in the glass substrate. Using this technique, it is possible for example to produce high-quality vias in glass, which is of interest for electronic packaging (or hermetic packaging).

Pulsed lasers can be used in the LIDE method, wherein the glass is then modified along the z-direction (=optical axis/surface normal of the glass substrate) with each laser shot (laser pulse). Typically no change in the beam profile used is applied here. In the LIDE method, in particular no individual small volumes (voxels) within the glass volume are thus differently processed with the laser, as is the case with other laser-based (for example ablative) glass processing methods. The glass substrate is thus not ablatively processed optically during the LIDE method, i.e. the desired material removal in the glass substrate is only achieved later during the wet-chemical etching step, but not using the laser radiation.

### SUMMARY

Proceeding from this previously known prior art, the invention is based on the object of expanding potential applications of the LIDE method.

The invention has in this respect recognized the following: The wet-chemical etching used during the LIDE method always begins on a substrate surface and proceeds from there into the depth (z-direction) of the glass substrate. Depending on the process parameters selected (in particular the material of the glass substrate, the etching solution used, and the temperature), the etching radius r in the xy-plane (=substrate plane) can decrease along the z-direction (i.e. normal to the substrate plane) to a greater or lesser extent, as a result of which edge profiles which have an inclination in relation to the z-axis are achievable (for example in the xz-plane). Only inclinations that correspond to an etching radius r decreasing with increasing depth z are possible here. The etching radius r on the substrate surface, however, always has the same size because it depends only on the etching solution and the total etching time, and therefore cannot be changed in a spatially resolved manner, which constitutes a central boundary condition of the LIDE method.

Owing to the respective etching radius r (z), which is produced in different xy-planes at different z-depths of the glass substrate, characteristic indentations can form in the side faces (in the direction of the xz-plane or yz-plane), which indentations are always concave because the etching solution etches isotopically in a specified xy-plane and therefore forms a convex etching front. This results in protruding glass ribs in these side faces which have been exposed by wet-chemical etching, which glass ribs protrude between the respective indentations and extend along the z-direction like the indentations. Depending on the process parameters selected, an inclination of the indentations can occur not only in the y-direction (for example in a structure extending in the x-direction), but also in the x-direction (for example at the tip of such a structure).

It has also been observed that the ribs, which should actually have purely geometric sharp edges, become rounded as the etching duration progresses, which appears to be caused by chemical processes in the micro-range. The ribs/indentations have a distance Lₓ, which corresponds to the pulse distance p, specifically from those laser points which cause the respective indentation to form. Since the ribs/indentations appear to be similar to the ribs on the outside of a seashell, these structures can be referred to as “sidewall scalloping.”

Taking into account these aspects, the features of claim 1 and/or of claim 2 are provided to achieve the aforementioned object according to the invention in a mechanical microstructure.

In particular it is thus possible according to the invention, for achieving the object in a mechanical microstructure of the type mentioned in the introductory part, for provision to be made to the effect that, for producing the microstructure in a deflection region of the microstructure (that is to say where the bending structure can move in the substrate plane or out of the substrate plane or where the micromechanical finger can move relative to the substrate), laser pulses were/are placed on two mutually opposite tool paths which have a respective maximum distance r perpendicular to an (outer) contour (in particular to concave indentations in the contour) along a direction of extent of the microstructure. This distance r corresponds exactly to an etching radius r from a wet-chemical etching step, which is/was used to expose the microstructure, wherein the etching radius r lies in a substrate plane of the glass substrate. In such an approach, the microstructure is thus designed monolithically (i.e. as a whole), as part of the glass substrate.

Provision is furthermore made for the laser pulses to have been (or be) placed during the production of the microstructure in such a manner that a respective spatial phase position φ(x) of respective laser pulse pairs along a direction of extent of the microstructure is set homogeneously within said deflection region. The homogeneous setting of the phase position should be implemented at least in sections in order to bring about a significant technical effect; preferably, the phase position can be set to be homogeneous along the entire deflection region, however.

Alternatively or in addition to these features, provision may also be made for those (preferably all) laser pulses (or laser points) which define an outer contour of the microstructure to be placed/have been placed on respective continuous (that is to say for example straight-lined or curved) tool paths, at least in said deflection region of the microstructure, during the production of the microstructure in order to achieve the object. Each of the tool paths has a maximum distance from the contour that corresponds exactly to an etching radius r of a wet-chemical etching step which was/is used for exposing the microstructure (from the glass substrate). The laser pulses on the tool path thus have a distance r from associated concave indentations in the contour. The laser pulses can preferably be placed on the respective tool path at a constant pulse distance p, at any rate at least in sections (for example placement of at least three adjacent laser pulses in succession at a pulse distance p on the respective tool path). It should be understood that, depending on the selected extent of the sidewall scalloping, the respective tool path may have a minimum distance of r-t_{y} from the contour, with t_{y} being the depth of the respective indentation in the side wall of the microstructure.

A phase position φ(x) can be understood to mean in particular the following spatial relationship describing the positioning of the laser points or the resulting indentations (described above): φ(x)=Δx/p′×360°. Here, φ(x) stands for the spatial phase position at a specific x-position along the direction of extent of the microstructure, Δx is an offset between two mutually opposite laser points along the direction of extent of the microstructure, and p′ is an effective pulse distance on a central axis of the microstructure (in the case of a rectilinear microstructure, p′=the geometric pulse distance p between two laser points which are directly adjacent on a tool path). This will be explained in more detail using the drawings.

A homogeneous phase position can be achieved, for example, when the phase position φ(x) along the direction of extent of the microstructure fluctuates by less than +/−60°, more preferably by less than +/−30°. The average phase position (or average phase angle φ or average phase offset φ) can be selected differently (for example φ=0° or φ=180°).

In other words, provision is made according to the invention for the laser pulses and the resulting etching radii (resulting during the wet-chemical exposure of the microstructure in the glass substrate) to be/have been placed uniformly along two opposite side faces (or side walls) of the microstructure in a manner such that mutually opposite laser point pairs (and the resulting indentations) always exhibit a uniform (that is to say for example approximately constant) offset Δx. The offset Δx can fluctuate slightly, for example due to the process or the geometry of the microstructure, but should always be selected so that a homogeneous phase position φ(x) is obtained. For example, the fluctuation of Δx can be so small that the phase position φ(x) in the deflection region of the microstructure changes by less than +/−60°, particularly preferably by less than +/−30°

Alternatively or in addition to controlling said phase position, the invention furthermore proposes to set the side wall scalloping of the microstructure in a targeted manner in order to set the mechanical properties in a desired manner (high homogeneity or targeted inhomogeneity). To achieve the object according to the invention in a mechanical microstructure of the type mentioned in the introductory part, provision therefore may be made, for producing the microstructure in a deflection region of the microstructure, for laser pulses to be/have been placed onto two mutually opposite tool paths which have a respective maximum distance r perpendicular to an (outer) contour (in particular to concave indentations in the contour) along a direction of extent of the microstructure, which distance corresponds to said etching radius r of the wet-chemical etching step. Since this etching radius r lies, as mentioned, in the substrate plane of the glass substrate, the contour has lateral concave indentations after the wet-chemical exposure which each have a curvature of the etching radius r and which are delimited by respective convex ribs. In order to improve the homogeneity of the mechanical properties of the microstructure or in order to generate in a targeted manner an inhomogeneity of the mechanical properties of the microstructure, the invention proposes to place the laser pulses in such a way that the degree of sidewall scalloping of the microstructure is set in a targeted manner, specifically at least in sections, but preferably along the entire deflection region.

The sidewall scalloping can be defined, for example, as a ratio t_{y}/r of the local etching radius r and a respective lateral depth t_{y} of the respective indentation. Targeted setting can here be understood, in particular, to mean that the sidewall scalloping in the entire deflection region becomes either consistently weaker or consistently stronger.

In other words, the extent of the sidewall scalloping, in particular the magnitude of the respective lateral depth t_{y}, is set in a targeted manner with spatial resolution along the direction of extent by appropriate placement of the laser pulses on the substrate plane. For example, provision may be made to the effect that, for bringing about sidewall scalloping which is consistently weak for the respective lateral depth t_{y}, at least in sections, but preferably along the entire deflection region, the following applies: t_{y}/r<0.1, preferably t_{y}/r<0.05, with r being the etching radius. In this case, the mechanical properties of the microstructure/bending structure will be very homogeneous. Provision may furthermore be made to the effect that the lateral depth t_{y} in the deflection region fluctuates by less than 40%, in particular by less than 20% or even by less than 10%.

If, by contrast, the aim is to generate a targeted inhomogeneity which can be exploited, for example, with respect to an actuator or sensor, provision may be made to the effect that, for the respective lateral depth t_{y}, at least in sections, but preferably along the entire deflection region, the following applies: t_{y}/r>0.1, preferably t_{y}/r>0.2, as a result of which strongly pronounced sidewall scalloping (in relation to the etching radius r) is achievable. In this case, the mechanical properties of the microstructure/bending structure will be inhomogeneous. Under certain circumstances, it may be the case in such configurations that the lateral depth t_{y} in the deflection region fluctuate by 50%, or the fluctuation is slight, with the result that strongly pronounced sidewall scalloping is homogeneously obtained, which however likewise results in the desired inhomogeneity.

The present invention(s) can be used in particular in order to form glass-based MEMS (micro-electro-mechanical systems), that is to say GMEMS, which exhibit excellent mechanical properties. A first example that should be mentioned is a cantilever with a width of less than 50 μm or even of less than 20 μm. At such small widths, there is a high risk of a spring fracture. By producing a homogeneous phase position of, for example, φ(x)=180°+/−30° or even φ(x)=180°+/−15°, and/or weak sidewall scalloping which is set to be homogeneous, the breaking strength of the cantilever can be significantly improved. As a result, such a spring structure can be reliably used in a GMEMS. The placement of the laser points on continuous tool paths having said maximum distance of r from the contour of the bending beam ensures that very thin bending beams can be reproducibly produced. This likewise results in advantages for the actuator/sensor system using such a bending beam.

Unlike customary MEMS based on silicon as the substrate material, glass is used in GMEMS in order to form the micromechanical structures, more precisely said micromechanical microstructure. Unlike silicon, glass is not a semiconductor but an insulator. However, by adding electrically conductive layers, for example metallic thin-film layers, to the glass, the electrical functionality of a GMEMS can be achieved.

The invention thus proposes to not simply leave the phase position to chance, but to set the phase position in a targeted manner in specific regions of a microstructure, specifically in the region of relevant deflection of the microstructure (deflection region) and to make it homogeneous, for example with a phase offset which has either a weak extent or a strong extent. The phase offset can be considered to be maximal at a phase of φ=180° and minimal at a phase of φ=0°. One advantage of such a configuration is that the mechanical properties of the microstructure can be controlled better, as will be explained in detail below.

For manufacturing the microstructure, it is possible for example as part of the LIDE method for provision to be made to the effect that a series of laser pulses are/were placed for this purpose on a laser line in order to introduce a modification into the glass substrate using laser radiation. The regions of the glass substrate which are/were modified in this way using laser radiation, can then be exposed in a subsequent (in particular the previously described) wet-chemical etching step.

The microstructure can have microscopic dimensions, for example with respect to a width (in the substrate plane) and/or height (normal to the substrate plane) of the microstructure. For example, the width/height can lie in the sub-mm range and be, for example, less than 100 μm, less than 50 μm or even less than 20 μm (in the case of very narrow cantilevers). The length of the microstructure, by contrast, can range from the sub-mm range to the mm-range and even into the cm-range, because in particular large GMEMS structures can be formed using LIDE.

The microstructure thus produced can thus have at least one microscopic dimension, such as the length and/or width and/or height (transversely to the substrate plane) of the microstructure. This is because the accuracy in the positioning of the laser pulses can be a few micrometers and, as a result, very fine microstructures can be exposed wet-chemically, with the high anisotropy that is achievable with the LIDE method also being advantageous. A microstructure configured according to the invention can have, for example, an aspect ratio (height:width) of at least 10:1, of at least 20:1, or even at least 50:1.

The microstructure can be designed for example as a self-supporting bending beam (cantilever), having one self-supporting end. However, it can also be anchored on both sides in the glass substrate, for example, preferably monolithically.

Depending on the application, the microstructure can thus be designed for in-plane deflection (in the xy-plane, corresponding to the substrate surface) and/or for out-of-plane deflection (in that case in the z-direction). In addition to such oscillation modes, torsional oscillations of the microstructure can be excitable as an alternative or in addition. For all such applications, the invention offers technical advantages relating to the mechanical properties of the glass microstructure, in particular in relation to breaking strength, homogeneity of the stiffness, and decrease in the cross-sensitivity.

A microstructure within the meaning of the invention can thus be designed as a micromechanical bending element, in particular as a micromechanical spring element, that is to say for example as a bending beam that is fixed at one or both sides, and for example also as a membrane, a torsion beam or for example as a movable finger of a comb structure, such as a micromechanical actuator or sensor. The movability of the finger can, for example, be achieved by the finger being suspended at a micromechanical spring element (the latter can be designed in particular according to the invention).

It should also be noted that each laser pulse can be assigned an associated laser point on the surface of the glass substrate which corresponds to the center of the point of incidence of the laser pulse on the glass substrate surface. The aforementioned tool paths correspond to those paths along which a laser head emitting the laser pulses is guided, wherein the laser head is typically guided at a constant z-distance from the substrate surface.

Due to the homogeneous nature of the phase position φ(x) of the microstructure (with respect to a contour of the microstructure), it is possible in particular to ensure that (i) a spring stiffness of the microstructure is minimized and/or that (ii) a homogeneity of the mechanical properties of the microstructure is set in a targeted manner (that is to say in particular minimized or maximized) and/or that (iii) a cross-sensitivity of the microstructure to a disturbing variable is set in a targeted manner (that is to say in particular minimized or maximized) and/or that (iv) a breaking strength of the microstructure is increased. In other words, the targeted control of the phase position φ(x) can control and optimize numerous mechanical properties of the microstructure.

It should be understood that microstructures as described herein and the associated production methods can thus be employed or used to achieve the four technical effects (i)-(iv) which were mentioned above. A low spring stiffness/high homogeneity/low cross-sensitivity/high breaking strength can be achieved by way of a large phase offset and/or by way of a small degree of sidewall scalloping. Inversely, a small phase offset, especially if the microstructure has a very small width, and/or a strong degree of sidewall scalloping can result in a comparatively high spring stiffness/low or poor homogeneity/high cross-sensitivity/low breaking strength of the microstructure.

Alternatively or in addition to the features described above, the object can also be achieved by a microstructure as claimed in independent claim 2. To achieve the object, it is thus possible in particular for provision to be made to the effect that a respective spatial phase position φ(x) of respective laser pulse pairs along a direction of extent of the microstructure within the deflection region is φ(x)=180°+/−60°, preferably φ(x)=180°+/−30°. Such configurations thus involve a large spatial phase offset φ. In such a configuration, it is additionally preferred if for a maximum width B of the microstructure within the entire deflection region: B<200 μm, in particular B<100 μm or even B<50 μm or B<20 μm. This is because such features can be used to produce or obtain microstructures which exhibit a very good mechanical reaction behavior and exhibit a high breaking strength despite their microscopic sizes.

Since both the pulse distance p and also the etching radius r are limited technically, and in view of the process costs, it is possible with a phase position of approximately 180° to produce softer and more homogeneous micromechanical springs with greater reproducibility. For example, smaller forces for deflection are necessary, less space is taken up or the fill factor is increased, and the peaks of the mechanical tension which are lower during deflection result in a higher breaking strength.

Such a phase position can consequently, in particular in connection with weak sidewall scalloping, lead to an excellent homogeneity of the mechanical properties of the microstructure, which is relevant for example when using the micro-actuator system or the micro-sensor system. For example, it is thus possible to set in a targeted manner specific desired characteristics of the micro-actuator system, i.e. the electrostatic reaction behavior of the microstructure can be influenced favorably. In this way, an improved actuator system and/or sensor system of a GMEMS can be achieved compared with microstructures in which the sidewall scalloping and/or the phase is not set in a targeted manner.

In order to realize such advantages, provision may furthermore be made for achieving weak sidewall scalloping, for the laser pulses to be placed such, and the microstructure to be exposed by etching such, that for a ratio of an average pulse distance p between adjacent laser pulses on one of the two tool paths (that is to say placed on the same tool path) and the etching radius r, preferably in the entire deflection region: p<r. With preference, it is even possible for: p<r/2. It should be emphasised here that the extent of the micro-scalloping is dependent only on the ratio p/r, but not on the selected spatial phase position defined by the offset Δx.

In the extreme case, in the case of semicircular indentations, for the length Lₓ of a respective indentation in the side wall of the microstructure: Lₓ=2r=p. In that case: p/r=2:1 or p=D=2r, with D being the etching diameter on the substrate surface.

In general, and in particular in the case of such configurations, it is additionally preferable if laser pulses which are directly adjacent have a minimum pulse distance of at least 3.0 μm or even less than 5.0 μm (on the respective tool path). This is because in this way, optical shadowing effects can be avoided and a homogeneous etching result can be obtained, which ensures that the extent of the sidewall scalloping can be set reproducibly and thus in a targeted manner during the production of the microstructure. On the other hand, it is advantageous in the case of weak sidewall scalloping if the pulse distance p remains below 10.0 μm, in particular below 7.0 μm, at any rate at least in the deflection region of the microstructure.

As has already been mentioned, the contour of the microstructure (in the region of the side walls) thus typically has lateral concave indentations after the wet-chemical exposure. These indentations each have a curvature having the etching radius r and are delimited by respective convex ribs. Provision can be made that, for a ratio of the local etching radius r and a lateral depth t_{y} of the respective indentations: t_{y}/r<0.1. Preferably, t_{y}/r<0.05 or even t_{y}/r<0.03. The depth t_{y} can be measured transversely to the direction of extent of the microstructure.

In addition or alternatively for the features just described, for a ratio of maximum width B of the microstructure transversely to the direction of extent and the lateral depth t_{y} of the respective indentation: t_{y}/B≤0.1, in particular t_{y}/B≤0.05. Such configurations also define very weak sidewall scalloping.

Such indentations delimited by ribs (which are more or less strongly pronounced and/or more or less rounded) can be subsumed, as mentioned, under the term “sidewall scalloping” because, similar to a seashell, the ribs structure the side faces of the microstructure which has been exposed by etching, but on a microscopic scale. The previously described two configurations consequently result in particularly flat/hardly pronounced sidewall scalloping, as a result of which a particularly low fluctuation in the width of the microstructure and thus a high homogeneity of the stiffness are achieved. It should be taken into account that the geometrical moment of inertia in the case of deflections in the substrate plane is a cubic function of the width (in the case of out-of-plane deflections, the geometrical moment of inertia by contrast increases linearly with the width and cubically with the height/thickness of the microstructure) and thus can fluctuate considerably in the case of pronounced sidewall scalloping of the local geometrical moment of inertia along the longitudinal axis of the microstructure. Adjacent ones of the ribs can have a mutual distance Lₓ, which corresponds exactly to the pulse distance p of the associated laser pulses.

The ribs can typically extend in the z-direction, i.e. normal to the substrate plane. The same also applies to the extent of the indentations themselves. The ribs and also the indentations can form an inclination to the z-axis (in particular at a taper angle φ), depending on the selected degree of anisotropy of the wet chemical etching process used.

Each of the indentations in the respective side wall of the microstructure can, in principle, be assigned to an associated laser pulse which was located at the distance r from the contour (=outer outline in the substrate surface/on the top side of the microstructure). The associated laser pulse or laser point (=point of incidence of the laser pulse on the glass substrate surface) is the cause for the formation of this indentation because the etching front proceeds isotopically from the laser point.

A configuration of the microstructure with low sidewall scalloping and a comparatively large phase offset φ(x) can be advantageous, for example, in order to enable a particularly high breaking strength and thus and in particular great deflections of the microstructure. This is because with lightly pronounced sidewall scalloping, in particular local peaks of the mechanical load are avoided because the geometrical moment of inertia is quite homogeneous. In sensor applications, by contrast, the sensitivity with which the microstructure can detect mechanical oscillations can be increased (for the same reasons).

Particularly weak sidewall scalloping will bring advantages for the homogeneity of the mechanical properties of a microstructure in particular when the width thereof is comparatively small, which then leads to a correspondingly high ratio of t_{y}/B for a given t_{y}. This becomes relevant in particular when the maximum width B of the microstructure (transversely to the direction of extent) falls below 100 μm or even 50 μm.

A different type of describing the phase offset between mutually opposite laser pulses or laser points is to state a step angle α, which a respective laser pulse pair in the deflection region of the microstructure 1 forms with respect to the direction of extent. The step angle α can be more than 2.5°, in particular more than 5°, and even more than 7° or even more than 9°, depending on the width of the microstructure. In particular for the step angle α: α=arctan(Δx/Dy), with Δx being the offset between the laser pulses forming the laser pulse pair with respect to one another along the direction of extent and Dy being the distance between the two opposite laser pulses (or the associated tool paths) transversely to the direction of extent. The step angle α increases as the width B decreases and the offset Δx/phase offset φ(x) increases.

If the offset between the laser points is, for example, Δx=p/2=5 μm at a pulse distance of p=10 μm, and thus φ(x)=Δx/p′×360°=180° and furthermore an etching diameter D=2r=20 μm is used, then at a spring width of B=10 μm the distance D_{y} between the tool paths can be for example D_{y}≈30 μm. This accordingly gives a step angle of α≈arctan(Δx/Dy)=arctan (5/30)=9.5°.

A further configuration makes provision for the fact that, for a ratio of an (in particular minimum or maximum) pulse distance p between two (directly) adjacent laser pulses on one of the two tool paths and a maximum width B of the microstructure transversely to the direction of extent: p/B≤1.0, preferably p/B≤0.75 or even p/B≤0.5. For high aspect ratios (for example t/B≥40) and/or very small spring widths (B≤20 μm), even for the microstructure: p/B<0.4, preferably p/B≤0.3. The pulse distance p used can be read from the distance Lₓ between two adjacent indentations in the side wall of the microstructure which were produced by wet-chemical etching.

In such configurations, the maximum width of the microstructure can be less than 50 μm, in particular less than 20 μm. For example, for a minimum pulse distance of pₘᵢₙ=5 μm and a maximum/nominal width of 10 μm of a microstructure used as a micromechanical spring, a ratio of p/B=0.5 can be obtained.

A technical effect that should be taken into account here is that the smaller the pulse distance p selected is and thus the smaller p/B is, the weaker the micro-scalloping will be and the more homogeneous the mechanical properties of the microstructure will therefore be.

Alternatively or in addition to all the features which have been described so far, the object can also be achieved by a microstructure as claimed in independent claim 7. To achieve the object, provision may in particular be made for a respective spatial phase position φ(x) of respective laser pulse pairs along a direction of extent of the microstructure within the deflection region of the microstructure to be φ=0°+/−60°, preferably φ=0°+/−30°. In such a configuration, provision may furthermore be made for a maximum width B of the microstructure within the entire deflection region: B<100 μm, in particular B<50 μm or even B<20 μm.

Such a phase position with only a very small phase offset φ can especially in connection with strongly pronounced sidewall scalloping lead to a comparatively large inhomogeneity of the mechanical properties of the microstructure. Even if this appears to be unfavorable at first glance, advantageous effects can arise from such an inhomogeneity, as will be explained in more detail below. For example, it is thus possible to set in a targeted manner specific desired characteristics of the micro-actuator system, i.e. the electrostatic reaction behavior of the microstructure can be influenced favorably. Owing to this it is possible to achieve an improved or qualitatively different actuator system compared with previously known microstructures, in particular of the kind that exhibit no sidewall scalloping and/or no such spatial phase distribution.

It is thus possible, in particular in the case of a very small homogeneous phase offset q, for achieving strongly pronounced sidewall scalloping, to place the laser pulses in such a way and to expose by etching the microstructure in such a way that for a ratio of an average pulse distance p between adjacent laser pulses on one of the two tool paths and the etching radius r, preferably in the entire deflection region: p>r or even p>1.2 r.

In the extreme case, with semicircular indentations (=maximally pronounced sidewall scalloping), for the length Lₓ of an indentation in the direction of extent: Lₓ=2r=D=p, i.e. in that case: p=2r (p is then at a maximum). If the pulse distance p is reduced starting from this maximum, the extent of sidewall scalloping continuously decreases. For values of p>1.0 r or even p>1.20 r, however, the sidewall scalloping will still be comparatively strongly pronounced. Such strongly pronounced sidewall scalloping can especially in connection with the previously explained phase position around 0° lead to interesting mechanical properties of the microstructure which can be technically exploited, in particular for new types of micro-actuator systems or micro-sensor systems.

Strongly pronounced sidewall scalloping can alternatively also be achieved by the following design or process parameters. For example, provision may be made for the contour of the microstructure (as already explained) to exhibit lateral concave indentations, which each have a curvature with the etching radius r and which are delimited by respective convex ribs. Furthermore, it is then possible that for a ratio of the etching radius r and a lateral depth t_{y} of the respective indentations: t_{y}/r>0.1, in particular t_{y}/r>0.2 or even t_{y}/r>0.3 (cf. tables 4 and 5).

In order to obtain a small phase offset, provision may furthermore be made (in addition or alternatively) for the previously described step angle α to be comparatively small. For example, the step angle α can, for example, be at most 4.0°, in particular at most 3.0°, preferably at most 2.0°. For such small step angles, which can be achieved by appropriate placement of the laser pulses (used to expose by etching the microstructure), a small phase offset φ(x) for a given etching radius r will be obtained, which for its part is largely specified for a specific substrate thickness and selected materials (glass substrate, etching solution).

Provision may furthermore be made according to a further configuration for a ratio of an, in particular minimal or maximal, pulse distance p between two adjacent laser pulses on one of the two tool paths and a maximum width B of the microstructure transversely to the direction of extent is: p/B≥0.5, preferably p/B≥0.75 or p/B≥1.0 or even p/B≥1.5. In particular the maximum width of the microstructure can be less than 100 μm, in particular less than 50 μm or even less than 20 μm. A technical effect to be taken into account here is that, the greater the pulse distance p selected is, and thus the greater p/B is, the more pronounced the micro-scalloping will be and the more inhomogeneous the mechanical properties of the microstructures will therefore be. This inhomogeneity can technically be of interest for new types of actuator and sensor mechanisms. For example, for a minimum pulse distance p of at least 10 μm and a maximum/nominal width of 10 μm of a microstructure used as a spring, a ratio of p/B=1.0 can be obtained.

As previously mentioned, the phase position φ(x) of a laser pulse pair can be defined particularly as φ(x)=360° Δx/p, with Δx being the offset of the two laser pulses of the laser point pair in the direction of extent of the microstructure, and p being the pulse distance between two adjacent laser pulses on one of the tool paths.

The invention can for example be used advantageously in micromechanical microstructures which are characterized in that the mutually opposite tool paths are approximately or strictly parallel to one another. However, configurations according to the invention of microstructures where mutually opposite tool paths enclose an angle or follow for example a respective curve are also possible. In the first two cases, the direction of extent of the microstructure can follow a straight line; in the latter case, by contrast, it can follow a curve. In such cases, the phase position may additionally change locally. By appropriately placing the laser points and selecting the pulse distances and the etching radius r (which is substantially determined by the substrate material, the etching time, and the etching liquid used), homogeneous phase positions can be obtained or formed even in such cases, at least in sections, along the direction of extent of the microstructure—either with a large or small phase position, depending on the intended objective.

In order to make the processing/production of the microstructure reproducible, provision may in particular be made for a minimum pulse distance of 3 μm and/or a maximum pulse distance of 15 μm, in particular of 10 μm, to be observed during the production of the microstructure in the deflection region. The fact that this condition has been met can be read for example from the extent of the sidewall scalloping, because—as already mentioned—the distances between ribs of the sidewall scalloping correspond exactly to the pulse distance of the associated laser pulses which have caused the respective side wall etching which has produced the ribs.

For example, it may make sense, especially if only slight sidewall scalloping is intended to be formed, to select the pulse distance to lie in the range 2-8 μm, preferably in the range 3-5 μm. Such values are possible for example for substrate thicknesses of between 100 μm and 500 μm. If, by contrast, the side wall scalloping can or should be more pronounced, it may make sense to select the pulse distance such that: p≥7 μm, in particular p≥10 μm.

The invention can be applied particularly advantageously in a micromechanical system. The latter can comprise at least one microstructure according to the invention or a multiplicity of microstructures according to the invention, for example in the form of a finger of a comb actuator or comb sensor.

The invention furthermore proposes a specific application or use of a microstructure according to the invention or a micromechanical system of this type. To achieve the object, in particular the use of a micromechanical microstructure made of glass, produced using laser-induced deep etching (LIDE), is proposed, specifically as part of a micromechanical actuator and/or as part of a micromechanical sensor and/or as part of a micromechanical carrier structure, preferably using electrostatic actuation or a capacitive sensor principle. The microstructure can, as previously explained, be designed, in particular according to any of claims 1 to 7, that is to say in particular with a comparatively large phase position and/or with sidewall scalloping which has been set in a targeted manner, in particular scalloping that is slight. With such use it is after all possible to use the targeted setting of the phase position φ(x) and/or the targeted extent of sidewall scalloping of the microstructure to improve the homogeneity of the mechanical properties of the microstructure, as has already been explained in detail. The microstructures can form spring elements of the actuator system/sensor system or, for example, the fingers of a micromechanical comb structure. This is relevant, for example, both for linear and rotational micro-actuator systems.

In addition, it is also possible to use a micromechanical microstructure produced using LIDE as part of a micromechanical actuator and/or as part of a micromechanical sensor, preferably using electrostatic actuation or a capacitive sensor principle, and in the process to set in a targeted manner the phase position φ(x) and/or the extent of sidewall scalloping of the microstructure in order to generate an inhomogeneity of the mechanical properties of the microstructure which may be used or is used with respect to the sensor or actuator. Such a microstructure of glass with preferably small phase offset and/or with pronounced sidewall scalloping can be used in particular to implement a micromechanical stepper motor. In this case, the step width of the motor can correspond exactly to the (local) period of the sidewall scalloping.

Finally, to achieve the object mentioned in the introductory part, a method for producing a micromechanical microstructure of glass using LIDE is proposed. In this method, laser pulses are placed in a deflection region of the microstructure on two mutually opposite tool paths, as has already been described in greater detail with reference to the microstructure according to the invention. As has been mentioned, the laser pulses or associated laser points (already in the layout) have a respective distance r from a contour (more specifically from respective associated concave indentations) of the microstructure, which distance corresponds to an etching radius r of a later wet-chemical etching step. This etching step is used to expose the microstructure in the glass substrate and thus to enable movability of the microstructure, either in the plane of the glass substrate or normal to the glass substrate. The method can be characterized in that the laser pulses are placed on the respective laser line in a manner such that (i) a homogeneous distribution of the spatial phase position φ(x) and/or (ii) a homogeneous extent of sidewall scalloping (which can be designed and defined as described above) along a direction of extent of the microstructure is obtained, which has already been explained in detail with reference to the microstructure. That is to say the laser pulses/laser points can be placed in such a way that a microstructure as described above, in particular according to any of claims 1 to 14, is exposed by wet-chemical etching.

Homogeneous distribution of the phase position can here be understood to mean in particular that the phase position φ(x) in the entire deflection region fluctuates by no more than +/−60°, preferably less than +/−30°, about an average phase value φ₀ (in particular independently of the profile of the microstructure). Homogeneous setting of the sidewall scalloping can, by contrast, be understood to mean in particular that for example the aforementioned lateral depth t_{y} in the entire deflection region fluctuates by no more than +/−30%, preferably less than +/−20%, or even by no more than +/−10% about an average lateral depth to. Depending on the desired property of the microstructure, the ratio to/r can be more or less large.

### BRIEF DESCRIPTION OF THE DRAWINGS

The invention will now be explained in more detail with reference to exemplary embodiments, but is not limited to these exemplary embodiments. Further configurations of the invention can be gathered from the following description of a preferred exemplary embodiment in conjunction with the general description, the claims, and the drawings. In the following description of various embodiments of the invention, elements of matching functions are provided with matching reference signs even for deviating constructions or designs.

In the figures:

FIG. 1 shows a first example of a micromechanical microstructure designed according to the invention in glass,

FIG. 2 shows a further example of a microstructure according to the invention,

FIG. 3 shows a further example of a microstructure according to the invention,

FIG. 4 shows a detailed and schematic view of the outer contour of a subsection of a microstructure designed according to the invention,

FIG. 5 shows a graph illustrating the width B (x) of a bending beam designed according to the invention as a function of the x-position for three cases of different phase positions φ(x),

FIG. 6 shows a further schematic illustration of a subsection of a microstructure according to the invention,

FIG. 7 shows an example of a microstructure according to the invention, which illustrates a curve shape in the x-substrate plane,

FIG. 8 shows a further schematic top view, similar to FIGS. 1-3, of a microstructure according to the invention, wherein numerous design or process parameters are illustrated,

FIG. 9 shows a further example of a microstructure according to the invention, in which the outer contour lines extend at an angle to one another,

FIG. 10 shows a cross-sectional view of a microstructure according to the invention with a medium taper angle,

FIG. 11 shows a cross-sectional view of a microstructure according to the invention with a greater taper angle,

FIG. 12 shows a further cross-sectional view of a microstructure according to the invention with a very small taper angle,

FIG. 13 shows a scanning electron microscope (SEM) image of a micromechanical comb structure having microstructures in the form of fingers, which are designed according to the invention, and

FIG. 14 shows a scanning electron microscope (SEM) image of a microstructure designed according to the invention in the form of a thin cantilever.

### DETAILED DESCRIPTION

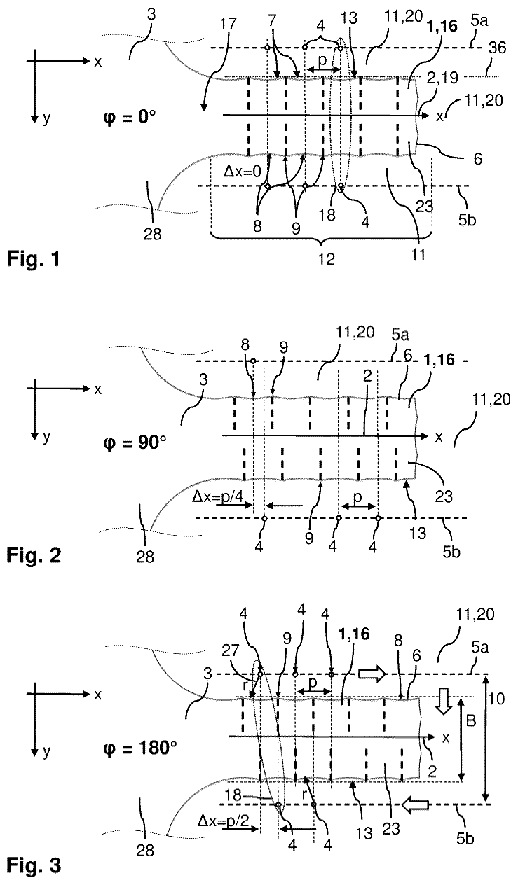

FIG. 1 schematically shows a micromechanical microstructure 1, exposed using the LIDE (laser-induced deep etching) method, in the form of a cantilever 16, which was exposed from a glass substrate 3 in the form of a glass wafer using wet-chemical etching. The view of FIG. 1 is a view from the top of the xy-plane of the glass substrate 3, which has a specific substrate thickness t_{glass} in the z-direction. As can be seen, the cantilever 16 is connected on one side to the “bulk” of the glass substrate 3 and there forms a flexure 17 or a one-sided mechanical suspension. The cantilever 16 can in principle be deflected in the xy-plane but also in the z-direction out of the plane.

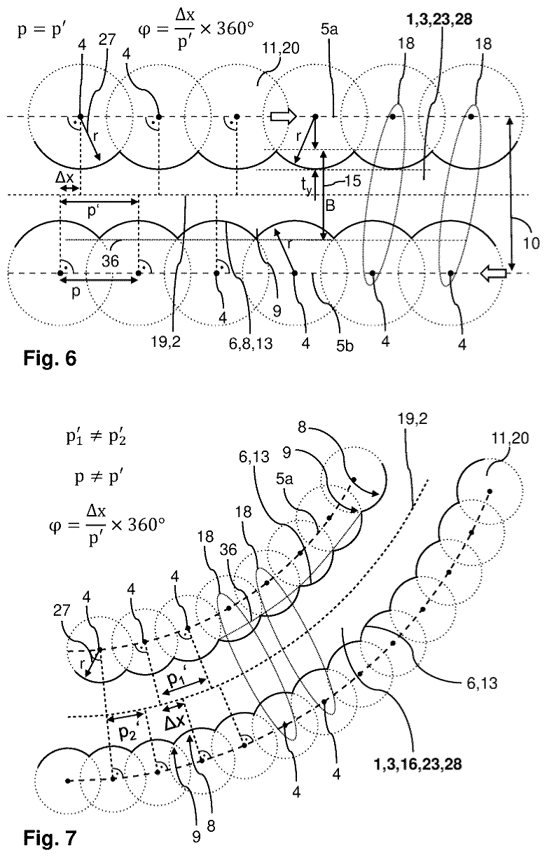

Using the LIDE (laser-induced deep etching) method, it is possible to cut fine glass pieces out of a glass substrate 3 or to expose them. Similar to the case involving a fretsaw, a contour 6 can be followed here using a laser, with the contour describing the outer boundary of the microstructure 1 to be exposed. For this purpose, the invention proposes that a laser head emitting the pulsed laser beam is moved along an associated tool path 5a, 5b, which follows the contour 6 at a specific distance (cf. FIG. 3). However, since the laser is pulsed, the glass substrate 3 is not continuously illuminated by the laser beam, but individual laser pulses 4 in the form of laser points 4 are placed at specific xy-coordinates on the surface of the glass substrate 3. Here, the laser points 4 can have a constant geometric pulse distance p (measured in μm in the substrate plane) and/or all of them can lie on said tool path 5a, 5b. The block arrows in FIG. 3 are intended to indicate the order in which the tool paths 5 are followed and the laser points 4 are placed (see also FIG. 6).

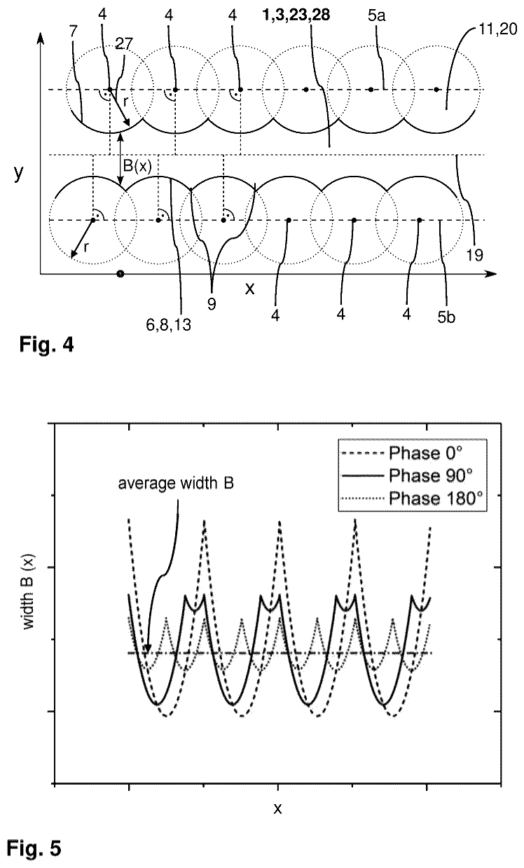

For example, if an elongate slot is to be introduced into the glass substrate 3, a specific number of laser pulses 4 are placed along a tool path 5, in each case at a pulse distance p, wherein typically each laser pulse 5 modifies the glass substrate 3 over the entire thickness. In the subsequent wet-chemical etching process, the etching solution etches its way from the surface in the z-direction into the substrate 3, wherein the etching speed in the xy-plane is isotropic, so that a disk-shaped etching profile 7 with rotational symmetry around a respective laser point 4 is obtained on the surface (cf. the circles in FIGS. 4 and 6 to 8). As a consequence, the contour 6 of the microstructure 1 which is finally exposed by etching has a distance r (=etching radius 27) from the center of the original laser point 4 (cf. FIG. 3 or FIG. 6). In other words, the exposed contour line 6 exhibits on the surface of the glass substrate 3 a maximum distance r from the tool path 5 (projected onto the substrate plane) on which the laser pulses 4 were placed. In other words, each of the laser pulses 4 has on the tool path 5 a distance r from the respective associated indentation 8, which is produced owing to the etching radius 27 starting from the respective laser pulse 4.

Owing to the etching radii r, concave indentations 8 which each have a curvature having the etching radius r 27 and are delimited by respective convex ribs 9, are thus formed in the respective side wall 13 of the microstructure 1, wherein these ribs 9 also extend along the indentations 8 of the z-direction (cf. FIGS. 1-3 and 4 and 6-9). These structures in the respective side wall 13 which are formed when exposing the microstructure 1 wet-chemically are referred to as sidewall scalloping, because the indentations 8 or the ribs 9 lying therebetween form a structure that is similar to that on the inside of a seashell.

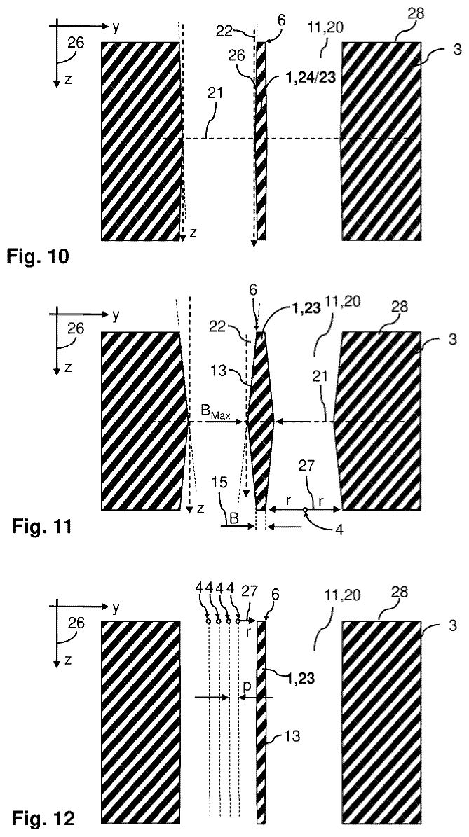

Depending on the process parameters selected and thus the degree of anisotropy of the wet-chemical etching, the etching radius 27 r in the xy-plane can decrease along the z-direction (i.e. normal to the substrate plane) to a greater or lesser extent, as a result of which profiles of the side walls 13 of the microstructure 1 which have an inclination or form a taper angle φ in relation to the z-axis, as is illustrated in FIGS. 10-12, are achievable (for example in the xz-plane). However, on the substrate surface, the etching radius 27 r, starting from each laser point 4, always has the same size. Furthermore, only inclinations that correspond to a decreasing etching radius 27 r with increasing depth z are possible. This is due to the fact that the wet-chemical etching always begins on the substrate surface and proceeds from there into the substrate depth. However, it is possible to start this process either on one side (FIG. 12) or on both sides (cf. FIGS. 10 and 11) of both substrate surfaces, with the result that correspondingly symmetric inclinations are obtained which taper in each case in the direction of a plane 21 (parallel to the xy-plane) which is arranged centrally (in the z-direction).

As is indicated in FIG. 11, which shows a cross section through a microstructure 1 according to the invention (wherein the direction of extent 2 of the microstructure 1 extends in the viewing direction toward the drawing), a single laser point 4 can already suffice to define a slot having a width of 2r between a microstructure 1 and the substrate 3, wherein the etching solution then forms starting from the laser point 4 (for example in the positive and negative y-direction as in FIG. 11) in the surface of the glass substrate 3 on both sides, an etching radius 27 r. The maximum width B 15, measured on the surface of the glass substrate 3 of the microstructure 1 (measured transversely to the direction of extent 2, that is to say in the y-direction in FIG. 11) can significantly deviate from the width BM, which the microstructure 1 exhibits in the illustrated central plane 21 of the substrate 3, depending on the selected taper angle φ.

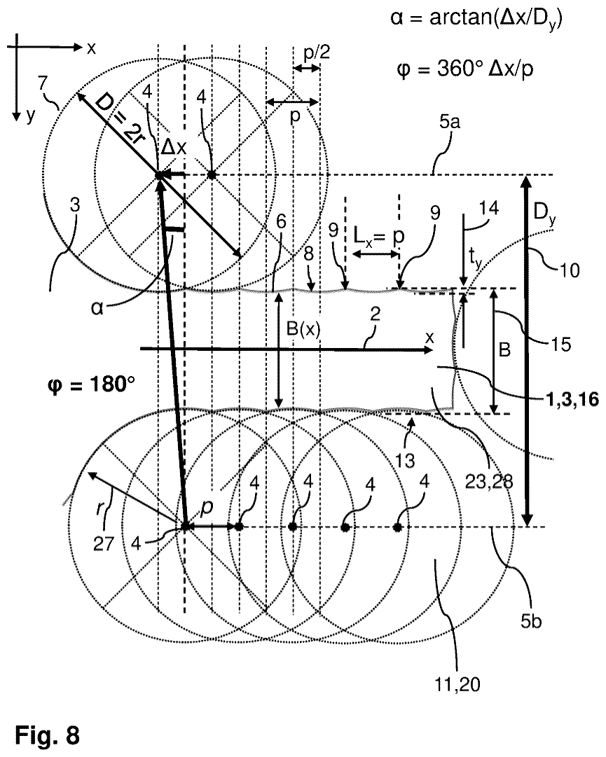

As is illustrated by FIG. 12, laser points 4 can, however, also be placed next to one another at a very close distance p, so that afterward the resulting etching radii r overlap (cf. in this respect FIG. 8). If the anisotropy of the laser-induced wet-chemical etching is selected to be very high, nearly perpendicular side walls 13 can be defined, as shown in FIG. 12.

FIG. 8 illustrates in detail how the microstructure 1 of FIG. 3 was manufactured. As can be seen from the circles, which illustrate in each case the disk-shaped etching profile 7 with the etching diameter D=2r, an entire series of laser pulses 4 was placed on two mutually opposite tool paths 5a and 5b in the deflection region 12 of the microstructure 1. Since the etching front 7 propagates isotopically in the xy-substrate plane, the laser pulses 4 each have a distance r from the final outer contour 6 of the microstructure 1, which distance corresponds exactly to the etching radius 27 r of the wet-chemical etching step used to expose the microstructure 1. As FIG. 3 shows, in each case two laser pulses 4, which are located on the mutually opposite tool paths 5a and 5b, can be combined to form one laser pulse pair 18. As FIGS. 1-3 show, the two laser pulses 4 of a respective laser pulse pair 18—with respect to the direction of extent 2 of the microstructure 1, which in these Figures corresponds to the x-axis-exhibit an offset Δx, which may lie for example between Δx=0 and Δx=p/2 when using a constant pulse distance p.

Depending on the extent of this offset Δx, a spatial phase position φ(x) or a spatial phase offset φ(x) between the respective laser points 4 of a laser point pair 18 is obtained. In the example of FIG. 1, the offset Δx=0, and thus the laser points 4 of the respective laser point pair 18 are arranged exactly in phase (φ=0°) with respect to the direction of extent 2. In the example of FIG. 3, the phase difference, by contrast, is maximum (φ=180°), because the offset Δx is there Δx=p/2, with p being the pulse distance, that is to say the distance between two directly adjacent laser points which are placed on the same tool path (e.g. 5b)—in this respect see FIG. 8.

The ratio p/r of pulse distance p and etching radius 27 r determines, by contrast, how strongly pronounced the indentations 8 of the sidewall scalloping are. The distance between the ribs 9 along the x-axis Lₓ corresponds exactly to the pulse distance Lₓ=p—see FIG. 8. in addition, for each indentation 9, a lateral depth t_{y} 14 can be determined, specifically measured transversely to the direction of extent 2, that is to say in the y-direction in FIG. 8.

In FIGS. 1-3, it is clear for example that in each case independently of the selected phase position the sidewall scalloping along the outer contour 6 in the deflection region 12 of the microstructure 1 is only weak, which can be seen by the small ratio t_{y}/r. This also applies to the microstructure shown in FIG. 7, because despite a curved profile, the laser pulses 4 have been placed there too such that the sidewall scalloping is consistently weak along the entire deflection region 12, with the result that this microstructure will exhibit homogeneous mechanical properties.

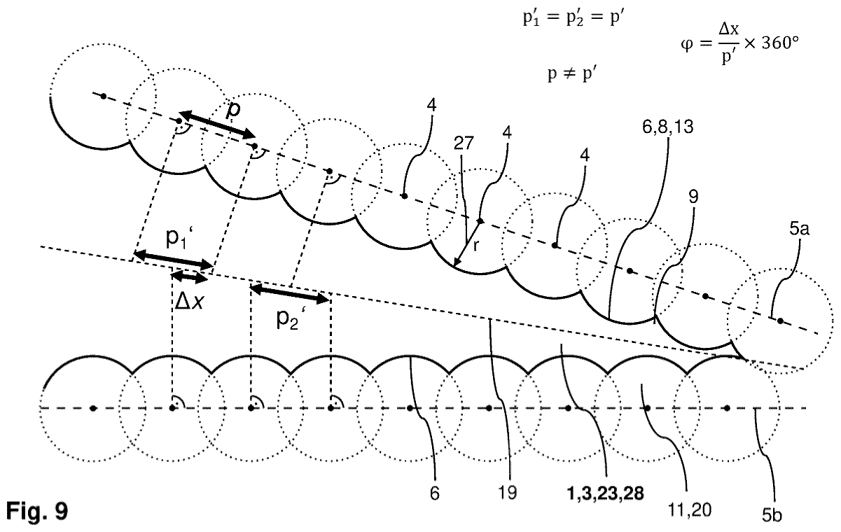

By contrast, FIG. 4 or, for example, FIG. 9 show the sidewall scalloping being (in each case) significantly more pronounced, that is to say the lateral depth t_{y} 14 is selected to be greater there compared to the etching radius r. Such pronounced sidewall scalloping alone already leads to an inhomogeneity of the mechanical properties of the bending structure 1, because for example the width B along the x-axis then fluctuates more strongly along the direction of extent x of the microstructure 1, as can be seen easily from FIG. 5. This fluctuation and thus the inhomogeneity will be all the higher for a given extent of the sidewall scalloping, the smaller the phase position selected is (compare for example the profile of the average width B at 0° and at 180° phase).

In both cases of FIGS. 1-3 and 4+9, however, it is clear that the extent of the sidewall scalloping in the entire deflection region 12 is set to be homogeneous, because the respective fluctuation of the lateral depth t_{y} 14 is selected to be very small, by appropriate placement of the laser points 4.

It can also be established that the laser points 4 in the approach according to the invention do not follow a specified grid, but are defined or placed in a targeted manner on the basis of the outer contour 6 of the desired microstructure 1 (i.e. on the basis of design parameters and geometry parameters of the microstructure 1) in order to achieve the desired phase position and/or the desired sidewall scalloping. This differentiates this process guidance for example from DEEP RIE (deep reactive ion etching), as has been used for a long time for structuring of silicon, where the extent of the ribs is specified only by process parameters of the dry etching, but is not set/specified in a targeted manner using a structure design.

FIG. 8 additionally illustrates that the two tool paths 5a and 5b have a distance D_{y} 10. This distance and the selected offset Δx here determine the step angle α formed by two laser points 4 of a respective laser point pair 18 with respect to the direction of extent 2, wherein α=arctan (Δx/D_{y}). The spatial phase position φ(x) is determined by contrast by φ=360° Δx/p, wherein the offset Δx can vary as a function of the x-coordinates of the laser pulse pair 18, with the result that the phase position φ(x) can fluctuate along the direction of extent 2 in principle.

FIGS. 4 and 6 illustrate how the extent of the sidewall scalloping, which can be read for example from the ratio t_{y}/r, acts on the homogeneity of the width B(x) of the microstructure 1 and thus also on the mechanical properties. The three curves of the graph in FIG. 5 illustrate how the width B(x) changes along the direction of extent 2 with the x-coordinate (and in the process adopts in each case a maximum width B 15), specifically for the three cases of a phase position of 0°/90°/180°, which are illustrated in FIGS. 1-3. As is shown by the horizontal dashed line in FIG. 5, three microstructures 1 are compared here, which each have the same average width B. The extent of the sidewall scalloping (measured in t_{y}/r) was likewise selected to be identical. The graph of FIG. 5 shows that for a spatial phase of φ=0°, the fluctuation of the width B (x) is the greatest.

For a spatial phase position of φ=180°, the microstructure 1, by contrast, exhibits the smallest fluctuation of the width B(x). A phase position of φ=180° consequently not only yields advantages with regard to a greater breaking strength, but, for the same average width B, the spring stiffness of the microstructure 1 can also be significantly reduced, because (for deflections of the microstructure in the substrate plane) they are a cubic function of the width B. For a phase position of φ=0°, the local spring stiffness will thus significantly fluctuate because the fluctuations of the spring width B are cubed, as a result of which peaks of the mechanical stress can arise which can cause the spring to break.

A micromechanical microstructure 1 made of glass, as illustrated in FIG. 3, which shows a phase position φ(x) of 180° and, by way of comparison, weakly pronounced sidewall scalloping, is therefore well suited for use as part of a micromechanical actuator or sensor, because this microstructure 1 is soft/sensitive, but also displays homogeneous mechanical properties, in particular a good breaking strength. Due to these properties, such a microstructure 1 can be used in particular to implement a high-quality electrostatic actuation/sensor system.

However, a phase position of φ=0°, as shown in FIG. 1, can also lead to interesting mechanical properties which can be successfully technically exploited, in particular if the sidewall scalloping is strongly pronounced. For example, a high inhomogeneity of the mechanical properties of the microstructure 1, caused for example by a high fluctuation of the width B (as illustrated for the case φ=0° in FIG. 5) can lead to a strong non-linear reaction behavior of the microstructure 1 in the case of electrostatic actuation, which can be exploited for example in a stepper motor.

As can be easily seen in FIGS. 1-3, however, the respective spatial phase position φ(x) of the respective laser pulse pairs 18 along the direction of extent 2 of the microstructure 1 within the entire deflection region 12 has been set to be homogeneous, wherein the phase position in FIG. 1 is φ=0°, in FIG. 2 is φ=90°, and in FIG. 3 is φ=180° Owing to the respective rectilinear profile of the microstructure 1, the phase position φ(x) fluctuates here only with respect to the accuracy with which the laser points 4 can be placed on the glass substrate 3.

As illustrated by FIG. 6, for a rectilinear profile of the microstructure 1, the effective pulse distance p′=p corresponds exactly to the geometric pulse distance p between two laser points 4 which are directly adjacent on a tool path 5.

FIG. 7 shows a further example of a microstructure 1 designed according to the invention, wherein this microstructure 1, however, has a curved profile 2, which can be easily seen from the central line 19. Even in the case of such a configuration, respective laser point pairs 18 can be considered. The effective pulse distance p′≠p can, however, as illustrated in FIG. 7, deviate from the geometric pulse distance p. Nevertheless, even for a profile of the microstructure 1 such as this, the respective spatial phase position φ can be set to be homogeneous. In the example of FIG. 7, the phase position fluctuates, at least in sections, slightly (by approximately +/−30°) about an average phase position of approximately φ=180°.

FIG. 9 shows a further example of a microstructure 1 according to the invention. Here too respective laser pulses 4 are arranged at a constant pulse distance p on two mutually opposite tool paths 5a and 5b, which, however, enclose an angle. Accordingly, the outer contour 6 of the microstructure 1 exhibits in the xy-plane a wedge-shaped profile. In this example, a spatial phase position φ can also be determined with respect to the illustrated central line 19 for respective laser pulse pairs 18. Even in this example, the phase position φ is set to be homogeneous, at least in sections, and therefore fluctuates only slightly around an average value.

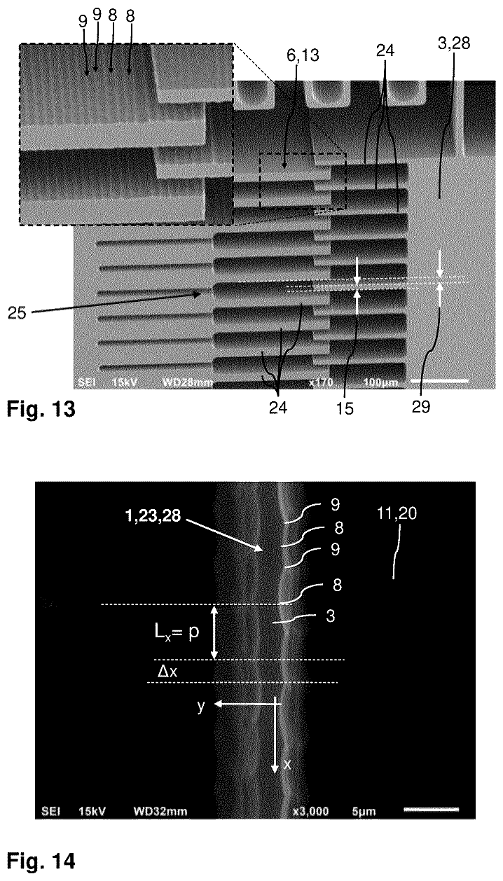

FIGS. 13 and 14 each show a scanning electron microscope (SEM) image in an oblique view from the top on respective microstructures 1, which, according to the invention, are formed with a homogenously set phase position φ. The indentations 8 and the ribs 9 therebetween, which extend in each case in the z-direction, that is to say transversely to the substrate plane 28, can be easily seen especially on the basis of the detailed view of FIG. 13, but also in FIG. 14. FIG. 14 shows a micromechanical spring element in the form of a thin bending structure 23, while the microstructures 1 of FIG. 13 are formed in each case as fingers 24 of an electrostatic comb actuator 25. The left-hand fingers 24 are movable in their respective longitudinal direction (=direction of extent 2), because these fingers 24 are suspended in their entirety movably in a main body of the glass substrate 3 (not shown in FIG. 13) using micromechanical spring elements 29.

A few exemplary design and process parameters of microstructures 1 formed according to the invention will be listed below in tables for different substrate thicknesses and substrate materials, specifically:

A) Examples of Microstructures According to the Invention with Weak Sidewall Scalloping

TABLE 1
Substrate material: Mempax/BF33

| | Substrate thickness [μm] | | | | |
|---|---|---|---|---|---|
| | 500 | 400 | 300 | 200 | 100 |
| Etching diameter | 25 | 20 | 20 | 15 | 15 |
| (D = 2r) [μm] | | | | | |
| Pulse distance | 3 | 3 | 3 | 3 | 3 |
| (p) [μm] | | | | | |
| Spring width (B) [μm] | 10 | 10 | 10 | 10 | 10 |
| Scalloping depth (t_{y}) | 0.09 | 0.11 | 0.11 | 0.15 | 0.15 |
| [μm] | | | | | |
| Taper (φ) [°] | 1.5 | 1.5 | 1.5 | 1.5 | 1.5 |
| p/r | 0.24 | 0.3 | 0.3 | 0.4 | 0.40 |
| ty/r | 0.0072 | 0.0113 | 0.0113 | 0.0202 | 0.02 |
| ty/B | 0.0090 | 0.0113 | 0.0113 | 0.0152 | 0.02 |
| p/B | 0.3 | 0.3 | 0.3 | 0.3 | 0.3 |

TABLE 2
Substrate material: AF32 (=glass substrate with a low coefficient
of thermal expansion similar to that of a silicon wafer)

| | Substrate thickness [μm] | | | | |
|---|---|---|---|---|---|
| | 500 | 400 | 300 | 200 | 100 |
| Etching diameter | 65 | 55 | 40 | 30 | 20 |
| (D = 2r)[μm] | | | | | |
| Pulse distance (p)[μm] | 5 | 5 | 5 | 5 | 5 |
| Spring width (B)[μm] | 10 | 10 | 10 | 10 | 10 |
| Scalloping | 0.1 | 0.11 | 0.16 | 0.21 | 0.32 |
| depth(t_{y})[μm] | | | | | |
| Taper(φ)[°] | 6 | 6 | 6 | 6 | 6 |
| p/r | 0.15385 | 0.1818 | 0.25 | 0.333 | 0.50 |
| ty/r | 0.00296 | 0.0041 | 0.0078 | 0.0140 | 0.03 |
| ty/B | 0.00963 | 0.0114 | 0.0156 | 0.0210 | 0.03 |
| p/B | 0.5 | 0.5 | 0.5 | 0.5 | 0.5 |

TABLE 3
Substrate material: Fused Silica

| Substrate thickness [μm] | 500 |
|---|---|
| Etching diameter (D = 2r) [μm] | 20 |
| Pulse distance (p) [μm] | 5 |
| Spring width (B) [μm] | 10 |
| Scalloping depth (t_{y}) [μm] | 0.32 |
| Taper (φ) [°] | 0.5 |
| p/r | 0.5 |
| ty/r | 0.03 |
| ty/B | 0.03 |
| p/B | 0.5 |

B) Examples of Microstructures According to the Invention with Pronounced Sidewall Scalloping

TABLE 4
Substrate material: Mempax/BF33

| | Substrate thickness [μm] | | | | |
|---|---|---|---|---|---|
| | 500 | 400 | 300 | 200 | 100 |
| Etching diameter (D = 2r) [μm] | 25 | 20 | 20 | 15 | 15 |
| Pulse distance (p) [μm] | 10 | 10 | 10 | 10 | 10 |
| Spring width (B) [μm] | 10 | 10 | 10 | 10 | 10 |
| Scalloping depth (t_{y}) [μm] | 1.04 | 1.34 | 1.34 | 1.91 | 1.91 |
| Taper (φ) [°] | 1.5 | 1.5 | 1.5 | 1.5 | 1.5 |
| p/r | 0.80 | 1.00 | 1.00 | 1.33 | 1.33 |
| ty/r | 0.08 | 0.13 | 0.13 | 0.25 | 0.25 |
| ty/B | 0.10 | 0.13 | 0.13 | 0.19 | 0.19 |
| p/B | 1 | 1 | 1 | 1 | 1 |

TABLE 5
Substrate material: AF32 (=glass substrate with a low coefficient
of thermal expansion similar to that of a silicon wafer)

| | Substrate thickness [μm] | | | | |
|---|---|---|---|---|---|
| | 500 | 400 | 300 | 200 | 100 |
| Etching diameter (D = 2r) [μm] | 65 | 55 | 40 | 30 | 20 |
| Pulse distance (p) [μm] | 15 | 15 | 15 | 15 | 15 |
| Spring width (B) [μm] | 10 | 10 | 10 | 10 | 10 |
| Scalloping depth (t_{y}) [μm] | 0.88 | 1.04 | 1.46 | 2.01 | 3.39 |
| Taper (φ) [°] | 6 | 6 | 6 | 6 | 6 |
| p/r | 0.46 | 0.55 | 0.75 | 1.00 | 1.50 |
| ty/r | 0.03 | 0.04 | 0.07 | 0.13 | 0.34 |
| ty/B | 0.09 | 0.10 | 0.15 | 0.20 | 0.34 |
| p/B | 1.5 | 1.5 | 1.5 | 1.5 | 1.5 |

TABLE 6
Substrate material: Fused Silica

| Substrate thickness [μm] | 500 |
|---|---|
| Etching diameter (D = 2r) [μm] | 20 |
| Pulse distance (p) [μm] | 5 |
| Spring width (B) [μm] | 10 |
| Scalloping depth (t_{y}) [μm] | 0.32 |
| Taper (φ) [°] | 0.5 |
| p/r | 0.5 |
| ty/r | 0.03 |
| ty/B | 0.03 |
| p/B | 0.5 |

As can be seen from the numerical values, in these examples the etching diameters D=2r range from a few μm, typically: r≤50 μm or even r≤20 μm or even r≤10 μm. For the ratio of etching diameter D=2r and substrate thickness t, typically at least: D/t≤1:5=0.2; for a very large substrate thickness (t≥400 μm), it may even be D/t≤1:20=0.05. The stated taper angle φ22 describes here the inclination of the side wall surfaces 13 of the microstructure 1 to the z-axis (=surface normal of the substrate)—compare in this respect FIGS. 10-12.

In the example of table 6, an aspect ratio (=substrate thickness: spring width) of the microstructure 1 of 100 is achieved. In this case, sidewall scalloping still is very weakly pronounced, with a ratio t_{y}/r=0.03. This shows that LIDE can be used to manufacture very homogenous spring structures with an enormous aspect ratio; these are advantageously suited to micromechanical systems.

In the examples of table 4, the extent of sidewall scalloping increases with decreasing substrate thickness. For instance, the following applies in the event of a substrate thickness of 100 μm: t_{y}/B=19% and t_{y}/r>20%. For the same substrate thickness of 100 μm, the ratio of lateral depth t_{y} of the indentation 8 to maximum width B 15 of the microstructure 1 is even 34% in table 5. Accordingly, clear indentations 8 or ribs 9 are formed in the sidewalls 13 of the microstructure 1 in these examples.

In summary, in order to extend the possible applications of the already known LIDE (laser-induced deep etching) method, this invention proposes, in the production of a micromechanical micro-structure 1 by placing a plurality of laser pulses 4 on a glass substrate 3 with a subsequent wet-chemical etching step for exposing the micro-structure 1, to precisely control the position of the laser pulses 4 that define the outer contour 6 of the micro-structure 1. In this way it becomes possible to control a spatial phase position q of mutually opposite laser pulses 4 or laser points 4, which are arranged on both sides of the microstructure 1, and form a respective laser pulse pair 18, but also an extent of what is known as sidewall scalloping. By controlling the phase position φ and/or the sidewall scalloping, it is possible to influence or set in a targeted manner the mechanical properties of the microstructure 1 favorably/in the desired form (cf. FIG. 8), which can be advantageously exploited for actuator systems or sensor systems.

### LIST OF REFERENCE SIGNS

1 Microstructure (may be designed in particular in the form of a micromechanical bending structure or movable finger)
2 Direction of extent (of 1)
3 Glass substrate
4 Laser pulse (the point of incidence on 3 defines a laser point with an xy-coordinate on the surface of 3)
5 Tool path (along which the laser head is guided and on which the laser pulses are placed)
6 Contour (of 1, in particular outer boundary of 1 in the substrate surface/on the top side of 1)
7 Etching profile (in the xy-plane, caused by 4)
8 (Concave) indentation (in sidewall of 1)
9 (Convex) rib (in the side wall of 1)
10 Tool path distance (or local y-distance between 4)
11 Modified regions (in 3)
12 Deflection region (of 1)
13 Side wall, or side wall surface (of 1)
14 Lateral depth (of 14)
15 (Maximum) width (of 1 transversely to 2)
16 Cantilever
17 Flexure
18 Laser pulse pair
19 Central axis or central line (of 1)
20 Region exposed (by wet-chemical etching)
21 Central plane (of 3)
22 Taper angle ¢
23 Bending structure (for example formed as a micromechanical spring element)
24 Movable finger (of 25)
25 Micromechanical comb structure
26 Surface normal (of 3=z-axis)
27 Etching radius
28 Substrate plane
29 Gap size

1. A microstructure (1) made of glass, the microstructure (1) comprising:
a glass substrate (3) that is exposed by laser-induced modification of the glass substrate (3) and subsequent wet-chemical anisotropic etching,
in which, in a deflection region (12), laser pulses (4) are placed on two mutually opposite tool paths (5a, 5b) which have a respective maximum distance r perpendicular to a contour (6) of the microstructure (1), said distance r corresponds to an etching radius (27) of a wet-chemical etching step, and the etching radius (27) lies in a substrate plane (28) of the glass substrate (3),
wherein the laser pulses (4) are placed such that a respective spatial phase position φ(x) of respective laser pulse pairs (18) along a direction of extent (2) of the microstructure (1) within the deflection region (12) is at least in sections, set to be homogeneous, wherein the spatial phase position φ(x) of the laser pulse pair (18) is defined as φ(x)=360° Δx/p, with Δx being an offset of the two laser pulses (4) of the laser pulse pair (18) in the direction of extent (2), and p being the pulse distance between two adjacent laser pulses (4) on one of the tool paths (5a or 5b).

2. A microstructure (1) made of glass, comprising:
a glass substrate (3) that is exposed by laser-induced modification of the glass substrate (3) and subsequent wet-chemical anisotropic etching,
wherein, for producing the microstructure (1) in a deflection region (12), laser pulses (4) are placed on two mutually opposite tool paths (5a, 5b) which have a respective maximum distance r perpendicular to a contour (6) along a direction of extent (2) of the microstructure (1), said distance corresponds to an etching radius (27) of the wet-chemical etching step, wherein the etching radius (27) lies in a substrate plane (28) of the glass substrate (3) and
wherein the contour (6) after the wet-chemical exposure has lateral concave indentations (8), which each have a curvature having the etching radius (27) and which are delimited by respective convex ribs (9), and
wherein the laser pulses (4) are placed such that an extent of a sidewall scalloping of the microstructure (1) is set in a targeted manner in order to improve a homogeneity of mechanical properties of the microstructure (1) or to generate in a targeted manner an inhomogeneity of the mechanical properties of the microstructure (1), and
the sidewall scalloping is defined as a ratio t_{y}/r, where r=the local etching radius (27) and t_{y}=a respective lateral depth (14) of the respective indentation (8).

3. The microstructure (1) as claimed in claim 1, wherein the respective spatial phase position φ(x) of the respective laser pulse pairs (18) along the direction of extent (2) of the microstructure (1) within the deflection region (12) is φ(x)=180°+/−60°.

4. The microstructure (1) as claimed in claim 1, wherein, for achieving weakly pronounced sidewall scalloping, the laser pulses (4) are placed and the microstructure (1) is exposed by etching such that: p<r, where p=a ratio of an average pulse distance between adjacent ones of the laser pulses (4) on one of the two tool paths (5) and r=the etching radius (27).

5. The micromechanical microstructure (1) as claimed in claim 1, wherein the contour (6) exhibits lateral concave indentations (8), which each have a curvature with the etching radius (27) r and which are delimited by respective convex ribs (9), and
t_{y}/r<0.1
where r=the local etching radius (27) and t_{y}=a lateral depth (14) of the respective indentations (8).

6. The micromechanical microstructure (1) as claimed in claim 1, wherein a respective step angle α, formed by a respective laser pulse pair (18) in the deflection region (12) with respect to the direction of extent (2), is at least 2.5°, and
for the step angle α: α=arctan(Δx/D_{y}), where Δx=an offset of the laser pulses (4), which form the laser pulse pair (18), with respect to one another in the direction of extent (2), and D_{y}=a distance between the two mutually opposite laser pulses (4) transversely to the direction of extent (2).

7. The micromechanical microstructure (1) as claimed in claim 1, wherein p/B≤0.5, where p=a pulse distance between two adjacent laser pulses (4) on one of the two tool paths (5) and B=a maximum width (17) of the microstructure (1) transversely to the direction of extent (2), and
the maximum width (17) of the microstructure (1) is less than 50 μm.

8. The micromechanical microstructure (1) according to claim 1, wherein the respective spatial phase position φ(x) of respective ones of the laser pulse pairs (18) along a direction of extent (2) of the microstructure (1) within the deflection region (12) is φ(x)=0°+/−60°, and B<100 μm, where B=a maximum width (15) of the microstructure (1) within the entire deflection region (12).

9. The micromechanical microstructure (1) as claimed in claim 8,
wherein, for achieving strongly pronounced sidewall scalloping, the laser pulses (4) are placed and the microstructure (1) is exposed by etching such that: p/r>1:2, where p=an average pulse distance p between adjacent ones of the laser pulses (4) on one of the two tool paths (5) and r=the etching radius (27).

10. The micromechanical microstructure (1) as claimed in claim 8, wherein the contour (6) has lateral concave indentations (8), which each have a curvature with the etching radius (27) and which are delimited by respective convex ribs (9), and
t_{y}/r>0.1, where r=the etching radius (27) and t_{y}=a lateral depth (14) of the respective indentations (8).

11. The micromechanical microstructure (1) as claimed in claim 8, wherein a respective step angle α, which is formed by a respective one of the laser pulse pairs (18) in the deflection region (12) with respect to the direction of extent (2), is at most 4.0°.

12. The micromechanical microstructure (1) as claimed in claim 8, wherein p/B>0.5, where p=a pulse distance between two adjacent ones of the laser pulses (4) on one of the two tool paths (5) and B=a maximum width (17) of the microstructure (1) transversely to the direction of extent (2), and
the maximum width (17) of the microstructure (1) is less than 100 μm.

13. The micromechanical microstructure (1) as claimed in claim 8, wherein the mutually opposite tool paths (5a or 5b)
run approximately or strictly parallel to one another, or
enclose an angle, or
follow a respective curve.

14. The micromechanical microstructure (1) as claimed in claim 1, wherein for producing the microstructure (1), in the deflection region (12) at least one of
a minimum pulse distance of 3 μm or
a maximum pulse distance of 15 μm
on the respective tool path (5a or 5b) is observed.

15. A micromechanical system, comprising
at least one of the microstructures (1) as claimed in claim 1.

16. A micromechanical actuator, sensor and/or carrier structure, comprising: the micromechanical microstructure (1) made of glass as claimed in claim 1,
wherein at least one of the phase position φ(x) or the extent of a sidewall scalloping of the microstructure (1) is set in a targeted manner in order to improve homogeneity of the mechanical properties of the microstructure (1).

17. A micromechanical actuator and/or sensor, comprising the micromechanical microstructure (1) made of glass as claimed in claim 8, wherein at least one of the phase position φ(x) or the extent of a sidewall scalloping of the microstructure (1) is set in a targeted manner in order to generate an inhomogeneity of the mechanical properties of the microstructure (1), which is exploited with respect to the actuator and/or sensor.

18. A method for producing a micromechanical microstructure made of glass by laser-induced deep etching (LIDE), the method comprising:
placing laser pulses (4) in a deflection region (12) of the microstructure (1) on two mutually opposite tool paths (5), which have a respective distance r from a contour (6) of the microstructure (1), which distance corresponds to an etching radius (27) of a subsequent wet-chemical etching step,
wherein the laser pulses (4) are placed on the respective laser line (5) for obtaining at least one of
a homogeneous distribution of the spatial phase position φ(x)
or
a homogeneous extent of a sidewall scalloping along a direction of extent (2) of the microstructure (1), and
exposing the microstructure by wet-chemical etching.

19. The micromechanical microstructure (1) as claimed in claim 1, wherein the phase position φ(x) along the direction of extent (2) fluctuates by less than +/−60°.

20. The micromechanical microstructure (1) as claimed in claim 3, wherein B<100 μm, where B=a maximum width (15) of the microstructure (1) within the entire deflection region (12).
